(19) United States
(12) Patent Application Publication
(10) Pub. No.: US 2014/0332498 A1
(43) Pub. Date: Nov. 13, 2014

(54) SUBSTRATE HOLDER, SUBSTRATE SUPPORTING APPARATUS, SUBSTRATE PROCESSING APPARATUS, AND SUBSTRATE PROCESSING METHOD USING THE SAME

(71) Applicant: CHARM ENGINEERING CO., LTD., Yongin-Si (KR)

(72) Inventors: Young Ki HAN, Seoul (KR); Young Soo SEO, Hwaseong-si (KR); Hyoung Won KIM, Hwaseong-si (KR); Chi Kug YOON, Anseong-si (KR); Sang Hoon LEE, Gwangju (KR)

(21) Appl. No.: 14/337,197

(22) Filed: Jul. 21, 2014

Related U.S. Application Data
(62) Division of application No. 12/863,388, filed on Jul. 16, 2010, now abandoned.

(30) Foreign Application Priority Data
Jan. 16, 2008 (KR) 10-2008-0004870
Jan. 16, 2008 (KR) 10-2008-0004871
Jan. 30, 2008 (KR) 10-2008-0009463
Feb. 5, 2008 (KR) 10-2008-0011600

(51) Int. Cl. H01J 37/32

(52) U.S. Cl. CPC H01J 37/32715; H01J 37/32568; H01J 37/3244; H01J 2237/3343
USPC 216/67; 156/345.43; 156/345.3; 156/345.33; 156/345.24

(57) ABSTRACT

Provided are a substrate holder, a substrate supporting apparatus, a substrate processing apparatus, and a substrate processing method. Particularly, there are provided a substrate holder, a substrate supporting apparatus, a substrate processing apparatus, and a substrate processing method that are adapted to improve process efficiency and etch uniformity at the back surface of a substrate.

### CROSS-REFERENCE TO RELATED APPLICATIONS

This application is a divisional of U.S. patent application Ser. No. 12/863,388, filed Jul. 16, 2010, which is a U.S. national phase application of PCT International Application PCT/KR2009/000211, filed Jan. 15, 2009, which claims priority to Korean Patent Application Nos. 10-2008-0004870, filed Jan. 16, 2008; 10-2008-0004871, filed Jan. 16, 2008; 10-2008-0009463, filed Jan. 30, 2008; and 10-2008-0011600, filed Feb. 5, 2008, the contents of which are incorporated herein by reference in their entirety.

### TECHNICAL FIELD

The present disclosure relates to a substrate holder, a substrate supporting apparatus, a substrate processing apparatus, and a substrate processing method, and more particularly, to a substrate holder, a substrate supporting apparatus, a substrate processing apparatus, and a substrate processing method that are adapted to improve process efficiency and etch uniformity at the back surface of a substrate.

### BACKGROUND ART

Generally, semiconductor apparatuses and flat display apparatuses are manufactured by depositing a plurality of thin layers on the front surface of a substrate and etching the thin layers to form devices having predetermined patterns on the substrate. That is, a thin layer is deposited on the front surface of a substrate by using a deposition apparatus, and then portions of the thin layer are etched into a predetermined pattern by using an etching apparatus.

Particularly, since such thin layer deposition and etch processes are performed on the same surface (front surface) of a substrate, foreign substances such as thin layers and particles deposited on the back surface of the substrate during the thin layer deposition process are not removed, and the remaining foreign substances cause various problems such as bending and misalignment of the substrate in a subsequent process. Therefore, a dry cleaning method is widely used for repeatedly cleaning the thin layers and particles deposited on the back surface of the substrate to remove the thin layers and particles, and then a subsequent process is performed on the substrate, so as to increase the yield of a semiconductor device manufacturing process.

In a conventional dry cleaning process for cleaning the back surface of a substrate, a substrate such as a semiconductor wafer is placed between a shield member and a lower electrode that are arranged in a closed chamber to face each other with a predetermined gap therebetween. Next, the substrate is lifted to a process position, and the lower electrode is lifted to adjust the gap (plasma gap) between the shield member and the lower electrode. The shield member is provided with an upper electrode disposed at a position facing the lower electrode and is used as a gas distribution plate for injecting gas toward the substrate. Next, the chamber is evacuated to a high vacuum state, and then reaction gas is introduced into the chamber. The introduced gas is excited into a plasma state by applying high-frequency power across the shield member and the lower electrode, and unnecessary foreign substances are removed from the back surface of the substrate using the plasma-state gas. Here, the substrate carried into the chamber is processed in a state where the substrate is supported on a substrate supporting apparatus provided in the chamber at a process position located between the shield member and the lower electrode.

However, since such a conventional substrate supporting apparatus has an opened side not to interfere with a carrying unit used to carry a substrate into a chamber, reaction gas injected to the back surface of a substrate supported by the substrate supporting apparatus may leak or split due to the opened side of the substrate supporting apparatus. This reduces the etch uniformity of the back surface of the substrate.

Furthermore, in the conventional substrate supporting apparatus, a substrate holder used to place a substrate thereon and a lower electrode are actuated by separate driving units. Therefore, the structure of the substrate supporting apparatus is complex and it is difficult to use the inside space of the chamber. In addition, since the driving units are individually controlled for actuating the substrate holder and the lower electrode, the process efficiency is low.

Moreover, since the substrate holder is moved from the bottom surface of the chamber to a considerably high position by the driving unit, it is difficult to make the substrate parallel with the lower electrode and make the gap between the shield member and the substrate uniform. Thus, the etch rate reduces at an edge portion of the substrate.

In addition, since the conventional substrate holder should be entirely repaired or replaced although the substrate holder is partially broken during a substrate processing process, the maintenance costs of the substrate processing apparatus are high, and the time required for re-operating the substrate processing apparatus is long due to a time necessary for preparing a new substrate holder.

In addition, since exhaust holes are uniformed formed in the conventional substrate holder for discharging plasma, process application range is restricted.

In addition, if a ring-shaped substrate holder is not used, plasma generated between a substrate and an electrode is non-uniformly or rapidly discharged, that is, plasma staying time varies or becomes too short. Thus, the substrate is not uniformly process.

### DISCLOSURE OF INVENTION

### Technical Problem

To obviate the above-mentioned limitations, the present disclosure provides a substrate holder, a substrate supporting apparatus, a substrate processing apparatus, and a substrate processing method. According to the present disclosure, the substrate holder is simple and partially replaced with a new part. Furthermore, leakage of plasma generated at the back surface of a substrate is prevented, and plasma staying time is constantly kept by using a substrate supporting apparatus including the substrate holder, so as to clean the back surface of the substrate effectively and improve the process efficiency. Furthermore, gas injected through a shield member is uniformly distributed across the substrate to improve the etch uniformity at the edge portion of the substrate.

### Technical Solution

In accordance with an exemplary embodiment, a substrate holder includes: a ring-shaped stage configured to receive an edge portion of a substrate thereon; a sidewall connected to a lower surface of the stage for supporting the lower surface of the stage; and an exhaust hole formed in the sidewall.

In accordance with another exemplary embodiment, a substrate supporting apparatus includes: an electrode unit; a buffer member disposed at an outer circumference of the electrode unit; a substrate holder disposed on the buffer member for spacing a substrate apart from the electrode unit by supporting an edge portion of the substrate; and an elevating member configured to move the electrode unit and the substrate holder upward and downward.

In accordance with another exemplary embodiment, a substrate processing apparatus includes: a chamber; a shield member disposed in the chamber; an electrode facing the shield member; and a substrate holder disposed between the shield member and the electrode, wherein the substrate holder includes: a ring-shaped stage configured to receive an edge portion of a substrate thereon; a sidewall connected to a lower surface of the stage for supporting the lower surface of the stage; and an exhaust hole formed in the sidewall.

In accordance with another exemplary embodiment, a substrate processing apparatus includes: a chamber; a shield member disposed in the chamber; an electrode unit facing the shield member; a substrate holder disposed between the shield member and the electrode for supporting an edge portion of a substrate; a buffer member connecting the electrode unit and the substrate holder; and an elevating member connected to a lower portion of the electrode unit, wherein the substrate holder includes: a ring-shaped stage configured to receive the edge portion of the substrate thereon; a sidewall connected to a lower surface of the stage for supporting the lower surface of the stage; and an exhaust hole formed in the sidewall.

In accordance with another exemplary embodiment, a substrate processing apparatus includes: a gas distribution plate configured to uniformly distribute reaction gas supplied from an outer source; a hard stopper protruding downward from a lower edge portion of the gas distribution plate; a lower electrode configured to interact with an upper electrode to form an electric field for exciting reaction gas supplied through the gas distribution plate into a plasma state; and a side baffle vertically protruding from an edge portion of the lower electrode for uniformly exhausting plasma reaction gas therethrough in a lateral direction and making contact with the hard stopper when the lower electrode is lifted to limit the lifting of the lower electrode.

In accordance with another exemplary embodiment, a substrate processing method includes: carrying a substrate into a chamber; loading the substrate onto a substrate holder; simultaneously lifting the substrate holder and an electrode unit disposed under the substrate holder; processing the substrate; and carrying the substrate out of the chamber.

### Advantageous Effects

According to the teaching of the present disclosure, plasma can be uniformly generated at the back surface of a substrate to improve the etch uniformity across the back surface of the substrate. In detail, leakage of reaction gas injected toward a substrate placed in the chamber is prevented by using the substrate holder having variously shaped and sized exhaust holes at its sidewall, so that plasma generated between the substrate and the electrode can be stayed for a constant time, and reaction gas can flow smoothly for uniform distribution across the back surface of the substrate.

Furthermore, the substrate holder may have a divided structure, and in this case, the substrate holder can be partially re-machined or replaced without having to re-machine or replace the substrate holder wholly when the substrate holder is broken. Therefore, maintenance machining can be easily performed, and maintenance costs can be reduced.

Furthermore, the substrate supporting apparatus can be configured so that the electrode unit and the substrate holder can be simultaneously lifted by the elevating member. In this case, the substrate supporting apparatus can have a simple structure, and space can be efficiently used.

Furthermore, since the substrate holder of the substrate supporting apparatus is lifted by the elevating member connected to the electrode unit, the horizontal position of a substrate placed on the substrate holder can be easily maintained.

Furthermore, since the substrate processing apparatus includes the substrate supporting apparatus configured to lift the electrode unit and the substrate holder using a single elevating member, the substrate processing apparatus can be easily controlled, and the process efficiency can be improved.

In addition, since the shield member of the substrate processing apparatus can be spaced apart from a substrate by a uniform gap, the substrate can be uniformly etched.

Moreover, since plasma gas is discharged through the exhaust holes of the side baffle, the plasma gas can stay at the edge portion of a substrate for a longer time, and thus the edge portion of the substrate can be uniformly etched. Therefore, process errors and manufacturing costs can be reduced.

### BRIEF DESCRIPTION OF DRAWINGS

Exemplary embodiments can be understood in more detail from the following description taken in conjunction with the accompanying drawings, in which:

FIG. 1 is a cross-sectional view illustrating a substrate processing apparatus in accordance with an exemplary embodiment;

FIG. 2 is a cross-sectional view illustrating a substrate processing apparatus in accordance with another exemplary embodiment;

FIG. 3 is a schematic view illustrating a substrate processing apparatus in accordance with another exemplary embodiment;

FIG. 4 is a block diagram illustrating electric connections of the substrate processing apparatus of FIG. 3;

FIG. 5 is a perspective view illustrating a substrate holder in accordance with an exemplary embodiment;

FIG. 6 is a perspective view illustrating a modification version of the substrate holder of FIG. 5;

FIG. 7 is a perspective view illustrating a substrate holder in accordance with another exemplary embodiment;

FIG. 8 is a perspective view illustrating a modification version of the substrate holder of FIG. 7;

FIG. 9 is a perspective view illustrating a substrate holder in accordance with another exemplary embodiment;

FIG. 10 is a perspective view illustrating a substrate holder in accordance with another exemplary embodiment;

FIG. 11 is a perspective view illustrating a substrate holder in accordance with another exemplary embodiment;

FIG. 12 is an exploded perspective view illustrating the substrate holder of FIG. 5 when the substrate holder is divided in a circumferential direction;

FIG. 13 is a perspective view illustrating an assembled state of the divided substrate holder of FIG. 12;

FIG. 14 is a perspective view illustrating an assembled state of the substrate holder of FIG. 7 when the substrate holder has a divided structure;

FIG. 15 is an exploded perspective view illustrating a substrate holder in accordance with another exemplary embodiment;

FIG. 16 is a cross sectional view illustrating the substrate holder of FIG. 15;

FIG. 17 is an exploded perspective view illustrating the vertically divided substrate holder of FIG. 15 after re-dividing the substrate holder in a circumferential direction;

FIG. 18 is a view illustrating a modification version of exhaust holes of a substrate holder in accordance with an exemplary embodiment;

FIG. 19 is a view illustrating a substrate supporting apparatus in accordance with an exemplary embodiment;

FIG. 20 is a view illustrating an operational state of the substrate processing apparatus of FIG. 1;

FIGS. 21 and 22 are views illustrating operational states of the substrate processing apparatus of FIG. 2; and

FIG. 23 is a flowchart for explaining a substrate processing method using the substrate processing apparatus of FIG. 2, in accordance with an exemplary embodiment.

### BEST MODE FOR CARRYING OUT THE INVENTION

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, like reference numerals refer to like elements throughout.

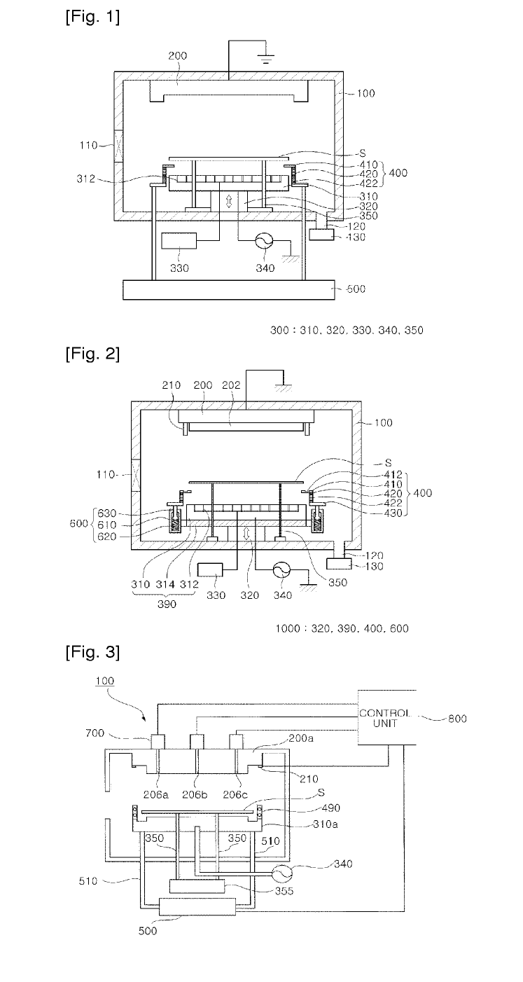

FIG. 1 is a cross-sectional view illustrating a substrate processing apparatus in accordance with an exemplary embodiment, and FIG. 2 is a cross-sectional view illustrating a substrate processing apparatus in accordance with another exemplary embodiment.

Referring to FIG. 1, the substrate processing apparatus of an embodiment includes a chamber 100, a shield member 200 provided at an upper region of the chamber 100, a gas injection unit 300 disposed at a side opposite to the shield member 200, and a substrate holder 400 disposed between the shield member 200 and the gas injection unit 300 for supporting a substrate (S).

Referring to FIG. 2, the substrate processing apparatus of another embodiment includes a chamber 100, a shield member 200 provided at an upper region of the chamber 100, and a substrate supporting apparatus 1000 disposed at a position opposite to the shield member 200.

Each of the chambers 100 of the substrate processing apparatuses of FIGS. 1 and 2 may have a cylindrical or rectangular box shape, and a space is formed in the chamber 100 for processing a substrate (S). The shape of the chamber 100 is not limited to a cylindrical or rectangular box shape; that is, the chamber 100 can have any other shapes corresponding to the shape of the substrate (S). A substrate gate 110 is formed in a sidewall of the chamber 100 for carrying the substrate (S) into and out of the chamber 100, and an exhaust part 120 is provided at the bottom surface of the chamber 100 for discharging reaction byproducts such as particles generated during an etch process to the outside of the chamber 100. An exhaust unit 130 such as a vacuum pump is connected to the exhaust part 120 for discharging contaminants from the inside of the chamber 100. The illustrated chamber 100 is a one-piece chamber; however, the chamber 100 can be configured by a lower chamber having an opened top side and a chamber lid used to cover the opened top side of the lower chamber.

Each of the shield members 200 has a circular plate shape and is disposed at an upper inner surface of the chamber 100. The shield member 200 prevents generation of plasma on the front surface of the substrate (S) disposed under the shield member 200 and spaced apart from the shield member 200 by several millimeters, for example, 0.5 millimeters. As shown in FIG. 1, a recess may be formed in the bottom surface of the shield member 200. The recess has a shape corresponding to the shape of the substrate (S) so that the front and lateral surfaces of the substrate (S) can be spaced apart from the bottom surface of the shield member 200, and the recess is formed to be lager than the substrate (S) for spacing the shield member 200 from the substrate (S) by a predetermined distance.

Alternatively, as shown in FIG. 2, a protrusion 202 may be formed on a center portion of the bottom surface of the shield member 200. The protrusion 202 may have a shape corresponding to the shape of the substrate (S) to place the front surface of the substrate (S) at a predetermined distance from the protrusion 202, and the protrusion 202 may be slightly larger than the substrate (S). Cylindrical hard stoppers 210 are protruded from a portion of the bottom surface of the shield member 200 where the protrusion 202 is not formed. The hard stoppers 210 are protruded downwardly, that is, in a direction toward the substrate supporting apparatus 1000. The lower ends of the hard stoppers 210 are lower than the horizontal bottom surface of the protrusion 202 formed on the bottom surface of the shield member 200. That is, when the substrate holder 400 is lifted, the hard stoppers 210 make contact with an upper portion of the substrate holder 400 so that the substrate (S) supported on the substrate holder 400 can be precisely spaced a predetermined distance apart from the bottom surface of the protrusion 202 formed on the bottom surface of the shield member 200. The protrusion 202 may have a circular ring shape to form a closed curve at the bottom surface of the shield member 200, or the protrusion 202 may have a divided ring shape.

A ground voltage is applied to the shield member 200, and a cooling member (not shown) may be disposed inside the shield member 200 to adjust the temperature of the shield member 200. The cooling member may protect the shield member 200 from plasma by keeping the shield member 200 lower than a predetermined temperature. A gas supply unit (not shown) may be connected to the shield member 200 to supply non-reaction gas to the front surface of the substrate (S). In this case, a plurality of injection holes (not shown) may be formed through the bottom surface of the shield member 200 for injecting non-reaction gas supplied from the gas supply unit to the front surface of the substrate (S).

In the substrate processing apparatus of FIG. 1, the gas injection unit 300 is disposed to face the shield member 200. The gas injection unit 300 includes an electrode 310, an elevating member 320 configured to raise and lower the electrode 310, a high-frequency power supply 340 configured to supply power to the electrode 310, and a gas supply unit 330 connected to the electrode 310 to supply reaction gas to the electrode 310. The substrate processing apparatus of FIG. 2 further includes an insulating plate 314 disposed at a lower side of an electrode 310 for supporting the electrode 310.

The electrode 310 may have a circular plate shape corresponding to the substrate (S). A plurality of injection holes 312 are formed through the top surface of the electrode 310 to inject reaction gas to the back surface of the substrate (S), and the gas supply unit 330 is connected to the injection holes 312 through the bottom side of the electrode 310 for supplying reaction gas to the injection holes 312. The elevating member 320 is connected to the bottom side of the electrode 310 for raising and lowering the electrode 310. The injection holes 312 formed through the top surface of the electrode 310 may have a shape such as a circular shape and a polygonal shape. The high-frequency power supply 340 is disposed under the electrode 310 for supplying high-frequency power to the electrode 310. Therefore, high-frequency power can be applied to reaction gas supplied into the chamber 100 through the electrode 310 so as to activate the reaction gas into a plasma state.

Lift pins 350 may be disposed in the chamber 100 in a direction perpendicular to the substrate (S). In the chamber 100, the lift pins 350 are fixed to a lower position and extend vertically through the electrode 310 so that the lift pins 350 protrude from the top surface of the electrode 310. The substrate (S) introduced into the chamber 100 is placed on the lift pins 350, and the number of the lift pins 350 may be at least three to support the substrate (S) stably. For example, an external robot arm (not shown) carries a substrate (S) into the chamber 100 and moves the substrate (S) horizontally to a position above the lift pins 350, and then the robot arm lowers the substrate (S) to place the substrate (S) on the top surfaces of the fixed lift pins 350. Instead of fixing the lift pins 350 to the inside the chamber 100, the lift pins 350 can be movably disposed inside the chamber 100.

The substrate holder 400 is used to support the edge portion of the substrate (S) placed on the lift pins 350 and move the substrate (S) to a process position. The substrate holder 400 is disposed in the chamber 100 between the shield member 200 and the gas injection unit 300 and configured to support the entire edge portion of the back surface of the substrate (S) placed on the lift pins 350 and move the substrate (S) to the process position. In the case of the substrate processing apparatus of FIG. 1, a driving unit 500 is disposed under the chamber 100 and connected to the bottom side of the substrate holder 400 for raising the substrate (S) placed on the lift pins 350 by actuating the substrate holder 400. In the case of the substrate processing apparatus of FIG. 2, the substrate holder 400 is connected to an electrode unit 390 through a buffer member 600, and an elevating member 320 is connected to the bottom side of the electrode unit 390, so as to raise the substrate (S) place on the lift pins 350.

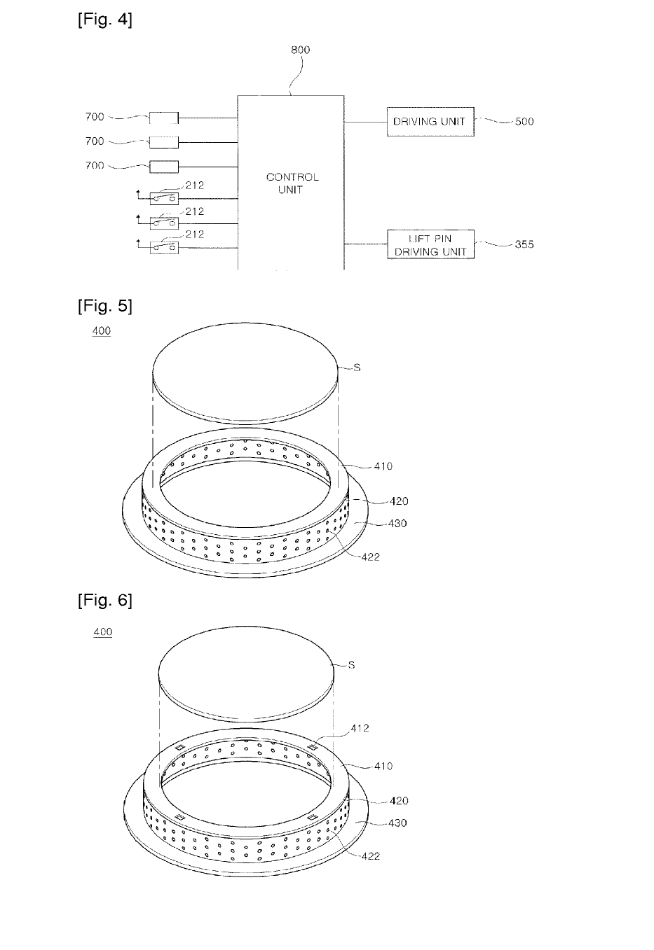

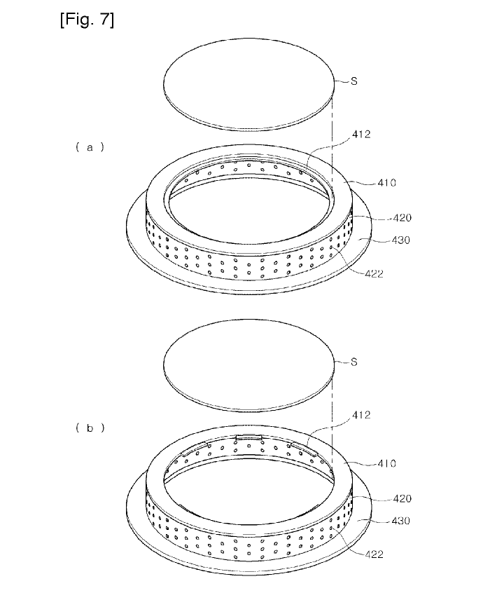

FIG. 3 is a schematic view illustrating a substrate processing apparatus in accordance with another exemplary embodiment, and FIG. 4 is a block diagram illustrating electric connections of the substrate processing apparatus of FIG. 3.

Referring to FIGS. 3 and 4, the substrate processing apparatus of the current embodiment includes: a gas distribution plate 200a configured to uniformly distribute reaction gas supplied from an outside gas source; hard stoppers 210 protruded downward from the edge portion of the bottom surface of the gas distribution plate 200a; a lower electrode 310a configured to form an electric field together with an upper electrode so as to activate reaction gas supplied through the gas distribution plate 200a into a plasma state; a side baffle 490 protruded vertically from the edge portion of the lower electrode 310a to discharge plasma reaction gas uniformly in a lateral direction and make contact with the hard stoppers 210 when the lower electrode 310a is lifted so as to limit the upward movement of the lower electrode 310a; a lift pin driving unit 355 configured to raise and lift pins 350 inserted through the lower electrode 310a; a driving unit 500 coupled to shafts 510 connected to the bottom side of the lower electrode 310a for moving the lower electrode 310a upward and downward; optical sensors 700 configured to sense a gap between the gas distribution plate 200a and a substrate (S) by casting laser beams through penetration holes 206a, 206b, and 206c formed through the gas distribution plate 200a; and a control unit 800 configured to receive gap-sensing signals from the optical sensors 700 and calculate the distance between the gas distribution plate 200a and the substrate (S) using the received gap-sensing signals for generating an interlock signal (error signal) if the calculated distance is greater than a predetermined value.

As shown in FIG. 4, the control unit 800 is electrically connected to: the optical sensors 700 configured to detect the gap between the gas distribution plate 200a and the substrate (S) by emitting laser beams through the penetration holes 206a, 206b, and 206c formed through the gas distribution plate 200a; contact switches 212 embedded in the hard stoppers 210 and configured to be turned on when the side baffle 490 is brought into contact with the hard stoppers 210 by lifting the lower electrode 310a; the lift pin driving unit 355 configured to raise and lower the lift pins 350; and the driving unit 500 configured to raise and lower the lower electrode 310a.

The substrate processing apparatus of the current embodiment is different from the substrate processing apparatus of FIG. 1 or FIG. 2, in that reaction gas is injected through the gas distribution plate 200a, and the optical sensors 700 and the control unit 800 are provided to detect a gap between the gas distribution plate 200a and the substrate (S). In addition, the side baffle 490 is provided in a chamber 100 instead of the substrate holder 400, and the lift pins 350 is configured to be movable upward and downward in the chamber 100. It is apparent that the optical sensors 700 and the control unit 800 used in the substrate processing apparatus of the current embodiment can also be used in the substrate processing apparatus of FIG. 1 or FIG. 2.

The substrate processing apparatus of the current embodiment will now be described in more detail.

The gas distribution plate 200a is disposed at an upper region of the chamber 100 to uniformly diffuse reaction gas supplied from an outside reaction gas source for performing a dry etch process in the chamber 100 by using plasma-state etch reaction gas. The penetration holes 206a, 206b, and 206c are formed through the gas distribution plate 200a, and the optical sensors 700 are arranged at regular intervals at the penetration holes 206a, 206b, and 206c. In the current embodiment, the number of the penetration holes 206a, 206b, and 206c is three, and the penetration holes 206a, 206b, and 206c are arranged on a circular arc at regular intervals. The gas distribution plate 200a may also function as an upper electrode.

Non-reaction gas is injected through a center portion of the gas distribution plate 200a, and reaction gas is injected through an edge portion of the gas distribution plate 200a. The lower electrode 310a is disposed at a lower position inside the chamber 100, and the substrate (S) is placed above the lower electrode 310a. At a lower inner position of the chamber 100, the electrode 310 is installed to place the substrate (S), and at an upper inner position of the chamber 100, an upper electrode (not shown) is installed at the gas distribution plate 200a which is spaced a predetermined distance from the lower electrode 310a. A plurality of etch gas supply holes (not shown) are formed through the upper electrode so that etch gas can be supplied into the chamber 100 through the etch gas supply holes.

The side baffle 490 is disposed at an edge portion of the lower electrode 310a so that plasma reaction gas can be discharged through the side baffle 490. The lower electrode 310a is connected to a high-frequency power supply 340, and the upper electrode is connected to another high-frequency power supply (not shown).

As a vacuum pump (not shown) is operated, the inside pressure of the chamber 100 is reduced to a high vacuum state. Next, the driving unit 500 is operated to lift the lower electrode 310a. The lower electrode 310a is lifted until the side baffle 490 makes contact with the hard stoppers 210 disposed at the edge portion of the gas distribution plate 200a. When the lower electrode 310a is lifted, the three optical sensors 700 emit laser beams toward the substrate (S) placed at the lower electrode 310a through the penetration holes 206a, 206b, and 206c formed through the gas distribution plate 200a so as to detect the distance between the gas distribution plate 200a and the substrate (S) by measuring the intensity of reflected laser beams. The three optical sensors 700 send the detection results to the control unit 800. The control unit 800 receives distance-sensing signals from the three optical sensors 700 and calculates the distance between the gas distribution plate 200a and the substrate (S), and if the calculated distance is larger than a predetermined value, the control unit 800 generates an interlock signal (error signal). If the side baffle 490 makes contact with the hard stoppers 210 as the lower electrode 310a is lifted, the contact switches 212 disposed inside the hard stoppers 210 are switched on. Then, the control unit 800 controls the driving unit 500 to stop the lower electrode 310a. In this way, the distance between the gas distribution plate 200a and the substrate (S) can be constantly adjusted each time so that the edge portion of the substrate (S) can be uniformly etched.

According to an embodiment, the control unit 800 may generate an interlock signal if the control unit 800 determines from sensing signals received from the optical sensors 700 that the substrate (S) is not horizontally placed at the lower electrode 310a.

Next, reaction gas is supplied to the inside of the chamber 100 through the etch gas supply holes for performing an etch process. High-frequency power is applied to the electrode 310 from the high-frequency power supply 340, and the upper electrode is connected to a ground voltage level. Thus, an electric field is formed between the lower electrode 310a the upper electrode, and free electrons are emitted from the lower electrode 310a.

The free electrons emitted from the lower electrode 310a are accelerated by energy received from the electric field, and while the accelerated free electrons pass through the reaction gas, the free electrons collide with the reaction gas so that energy can be transferred to the substrate (S). As this operation is repeated, positive ions, negative ions, and atomic groups coexist in the chamber 100 (a plasma state). In the plasma state, positive ions collide with the substrate (S) disposed above the lower electrode 310a so that a predetermined region of the substrate (S) can be etched.

In the related art, plasma is non-uniformly generated in a chamber, and thus ion density at the edge portion of a substrate is also not uniform. According to the current embodiment, however, since plasma reaction gas is discharged through the side baffle 490 disposed at the edge portion of the lower electrode 310a, the plasma reaction gas can stay at the edge portion of the substrate (S) more uniformly for a loner time, and thus the ion density at the edge portion of the substrate (S) can be uniformly maintained to prevent etch errors.

Hereinafter, the substrate holder 400 will be described in more detail with reference to the accompanying drawings in which exemplary embodiments are shown.

Referring to FIG. 5, according to an embodiment, the substrate holder 400 includes a stage 410 configured to place a substrate (S) thereon, and a sidewall 420 provided at a lower side of the stage 410. The stage 410 has a ring shape with opened top and bottom sides, and almost the entire edge portion of the back surface of the substrate (S) can be placed on the top surface of the stage 410. In the current embodiment, the stage 410 has a circular ring shape; however, the stage 410 can have any other shape according to the shape of the substrate (S). The sidewall 420 has a cylindrical shape with a vertical penetration opening at its center portion, and the top surface of the sidewall 420 is coupled to the bottom surface of the stage 410. The sidewall 420 may be coupled to the stage 410 using an additional coupling member or an adhesive member. A plurality of radial exhaust holes 422 are formed through the sidewall 420, so that reaction gas can be discharged away from the electrode 310 (refer to FIG. 1) through the exhaust holes 422 of the sidewall 420. The exhaust holes 422 may have a circular or polygonal shape, or some of the exhaust holes 422 may have a circular shape and the other may have a polygonal shape. A supporting part 430 may protrude outward from a bottom surface portion of the sidewall 420. In this case, the top surface of the driving unit 500 (refer to FIG. 1) may be coupled to a lower portion of the supporting part 430 for moving the substrate holder 400 upward and downward. In the current embodiment, the stage 410 and the sidewall 420 are separate parts; however, the stage 410 and the sidewall 420 can be formed in one piece.

As described above, the substrate holder 400 may further include the supporting part 430 protruding outward from the lower bottom surface portion of the sidewall 420. In the substrate processing apparatus of FIG. 1, the supporting part 430 may be connected to the driving unit 500 that is inserted through the bottom side of the chamber 100. In the substrate processing apparatus of FIG. 2, the supporting part 430 may be connected to the buffer member 600 connected between the substrate holder 400 and the insulating plate 314.

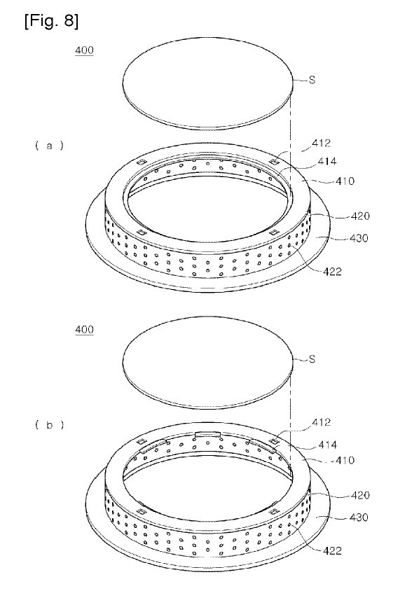

Referring to FIG. 6, a modified version of the substrate holder 400 of FIG. 5 is illustrated. According to the modified version, a plurality of recesses 412 may be formed in the top surface of the stage 410. When the substrate holder 400 is lifted to place the substrate (S) at a process position, the recesses 412 may be engaged with the hard stoppers 210 (refer to FIG. 2) formed on the bottom surface of the shield member 200 (refer to FIG. 2). The recesses 412 formed in the modification version of the substrate holder 400 are optional structures.

Referring to FIG. 7, according another embodiment, the substrate holder 400 includes a ring-shaped stage 410, a protrusion 412 formed on the inner circumference of the stage 410, and a sidewall 420 coupled to the bottom surface of the stage 410 and including a plurality of exhaust holes 422.

The protrusion 412 extends along the inner circumference of the stage 410. In detail, as shown in FIG. 7(a), the top surfaces of the protrusion 412 and the stage 410 may have different heights, and the protrusion 412 may extend along the inner circumference of the stage 410 to form a closed curve. In this case, almost the entire edge portion of the back surface of a substrate (S) may be placed on the top surface of the protrusion 412 formed along the inner circumference of the stage 410, and the lateral surface of the substrate (S) may be spaced apart from the inner circumference of the stage 410. Alternatively, the protrusion 412 may be discretely formed along the inner circumference of the stage 410 as shown in FIG. 7(b). In this case, when a substrate (S) is placed on the protrusion 412, the back surface of the substrate (S) may make partial or point contact with the top surfaces of the discrete parts of the protrusion 412.

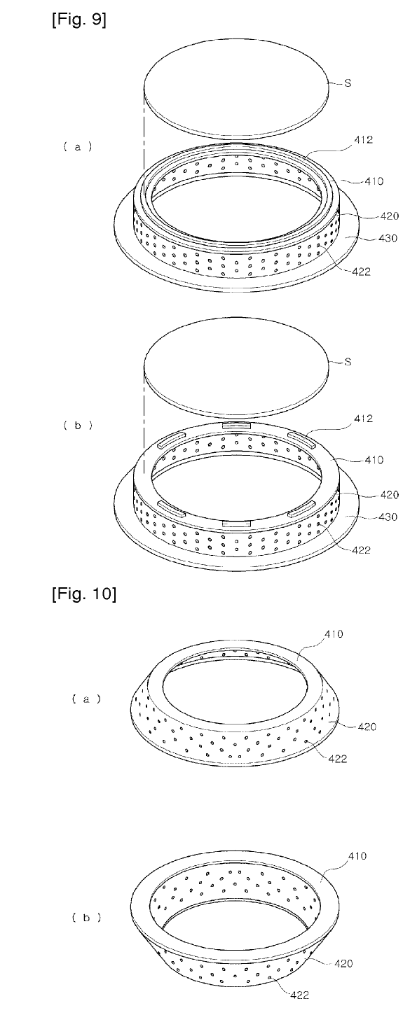

Referring to FIG. 8, a modified version of the substrate holder 400 of FIG. 7 is illustrated. According to the modified version, a plurality of recesses 412 may be formed in the top surface of the stage 410 for engaging with the hard stoppers 210 (refer to FIG. 2) formed on the bottom surface of the shield member 200 (refer to FIG. 2).

Referring to FIG. 9, according another embodiment, the substrate holder 400 includes a ring-shaped stage 410, a protrusion 412 formed on the top surface of the stage 410, and a sidewall 420 coupled to the bottom surface of the stage 410 and including a plurality of exhaust holes 422. The protrusion 412 extends upward from the top surface of the stage 410 for receiving a substrate (S) thereon. The protrusion 412 may be formed on the top surface of the stage 410 to form a closed curve as shown in FIG. 9(a), or the protrusion 412 may be discretely formed on the top surface of the stage 410 as shown in FIG. 9(b). Referring to FIG. 9, the substrate (S) may be placed on the top surface of the protrusion 412; however, the present invention is not limited thereto. For example, the substrate (S) may be placed inside the protrusion 412 so that the lateral surface of the substrate (S) may face the inner lateral surface of the protrusion 412. A substrate (S) can be stably placed at the stage 410 by disposing the substrate (S) on the top surface of protrusion 412 or inside the protrusion 412 as shown in FIGS. 7 through 9.

Referring to FIG. 10, according another embodiment, the substrate holder 400 includes a ring-shaped stage 410 and a sloped sidewall 420 provided at a lower side of the stage 410. The sidewall 420 has a cylindrical shape with a vertical penetration opening, and the top surface of the sidewall 420 is coupled to the bottom surface of the stage 410. A plurality of exhaust holes 422 are formed through the sidewall 420. The exhaust holes 422 may have various shapes. As shown in FIG. 10(a), the sidewall 420 may be sloped downwardly and outwardly from the stage 410 so that the sidewall 420 may have a downwardly increasing diameter, or as shown in FIG. 10(b), the sidewall 420 may be sloped downwardly and inwardly from the stage 410 so that the sidewall 420 may have a downwardly decreasing diameter.

In the current embodiment, the sidewall 420 of the substrate holder 400 is sloped so that reaction gas injected toward the back surface of a substrate (S) placed on the top surface of the stage 410 can be smoothly guided to the back surface of the substrate (S) without stagnating at the inner surface of the sidewall 420. Therefore, the reaction gas can be uniformly distributed across the back surface of the substrate (S). In addition, since plasma can be uniformly generated across the back surface of the substrate (S) owing to the uniform distribution of the reaction gas, the back surface of the substrate (S) can be uniformly etched.

Referring to FIG. 10, according another embodiment, the substrate holder 400 includes a plurality of stages 410 and a plurality of sidewalls 420 provided at lower sides of the stages 410. Almost the entire edge portion of the back surface of a substrate (S) can be placed on the stages 410. The stages 410 are arranged in a ring shape and have opened top and bottom sides. The sidewalls 420 are provided at the lower sides of the stages 410, that is, the sidewalls 420 are coupled to corresponding stages 410, respectively. A plurality of exhaust holes 422 may be formed through the sidewalls 420 for discharging reaction gas injected toward the back surface of the substrate (S). The exhaust holes 422 may be formed through at least of the sidewalls 420.

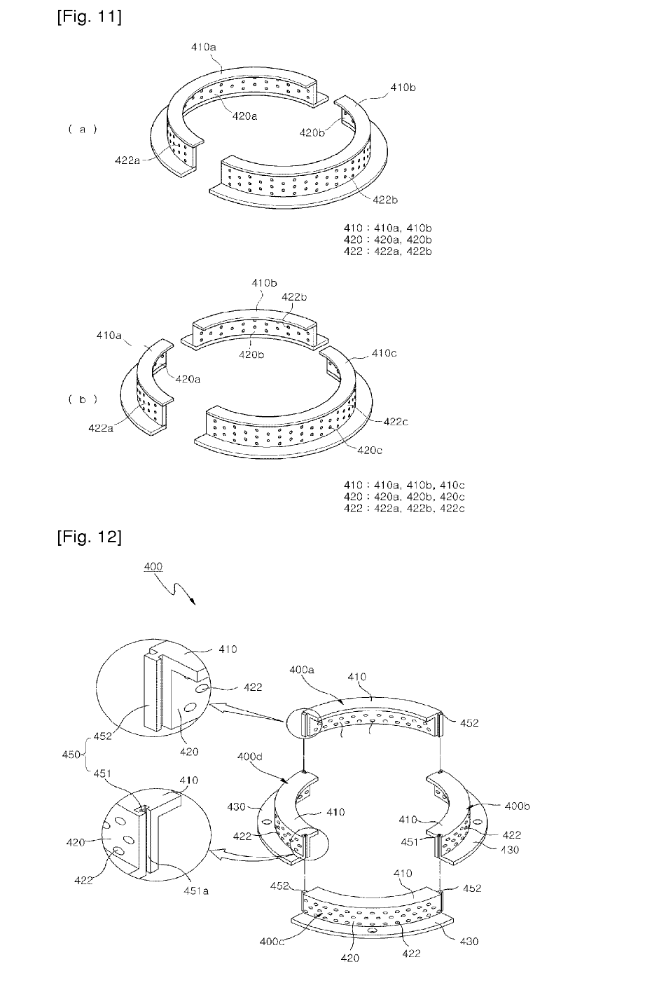

The substrate holder 400 may be divided into two parts as shown in FIG. 11(a) or three parts as shown in FIG. 11(b). However, the present invention is not limited thereto. For example, the substrate holder 400 may be divided into four parts or more. By dividing the substrate holder 400 as explained above, the substrate holder 400 may be easily machined during a manufacturing process.

The substrate holders 400 of the previous embodiments illustrated in FIGS. 5 through 10 can be divided like the substrate holder 400 of the current embodiment.

In the case where the substrate holder 400 is divided as explained above, circumferential coupling structures 450 may be provided for the divided parts of the substrate holder 400 as shown in FIGS. 12 through 17.

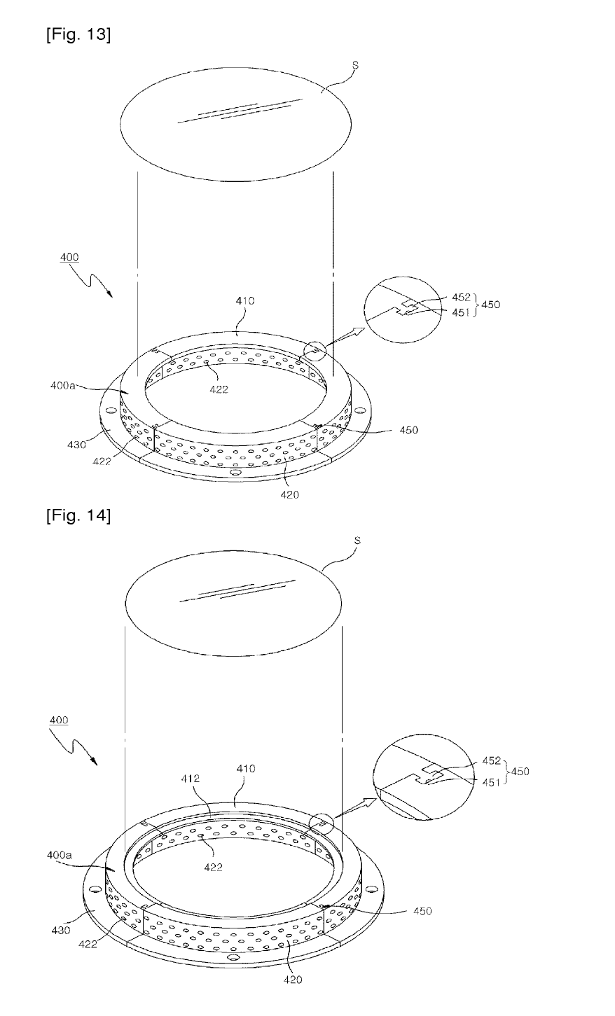

FIGS. 12 and 13 are an exploded perspective view and an assembled perspective view illustrating the substrate holder of FIG. 5 when the substrate holder is divided into parts, and FIG. 14 is a perspective view illustrating an assembled state of the substrate holder of FIG. 7 when the substrate holder has a divided structure.

Referring to FIGS. 12 through 14, sub parts 400a, 400b, 400c, and 400d of the divided substrate holder 400 include at least one circumferential coupling structure 450. The circumferential coupling structure 450 includes a coupling groove 451 and a coupling part 452. The coupling groove 451 is vertically formed in a side portion of one of the sub parts 400a, 400b, 400c, and 400d, and the coupling part 452 is formed on a side portion of another of the sub parts 400a, 400b, 400c, and 400d adjacent to the coupling groove 451. The coupling part 452 has a shape corresponding to the shape of the coupling groove 451. Stoppers 451a are formed along both sides of the coupling groove 451 for holding both sides of the coupling part 452 and preventing lateral escaping of the coupling part 452. The coupling part 452 can be released from the coupling groove 451 by vertically sliding the coupling part 452 along the coupling groove 451. The coupling groove 451 and the coupling part 452 may have various shapes such as rectangular, polygonal, and circular shapes.

In the current embodiment, a pair of coupling grooves 451 or a pair of coupling parts 452 are formed at each of the sub parts 400a, 400b, 400c, and 400d of the substrate holder 400. In another embodiment, a coupling groove 451 and a coupling part 452 may be formed at each of the sub parts 400a, 400b, 400c, and 400d of the substrate holder 400. A plurality of connection holes may be formed through the supporting part 430 for easily coupling the divided substrate holder 400 to the driving unit 500 (refer to FIG. 1) or the buffer member 600 (refer to FIG. 2).

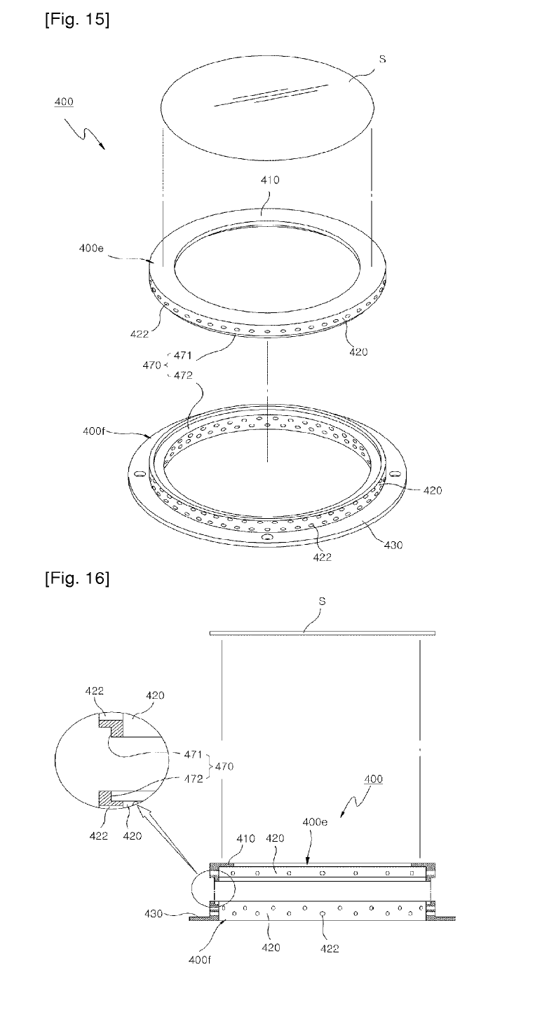

FIGS. 15 and 16 are an exploded perspective view and a cross sectional view illustrating a substrate holder 400 in accordance with another exemplary embodiment.

Referring to FIGS. 15 and 16, the substrate holder 400 of the current embodiment is vertically divided into sub parts 400e and 400f, and at least one vertical coupling structure 470 is provided for coupling the sub parts 400e and 400f of the divided substrate holder 400.

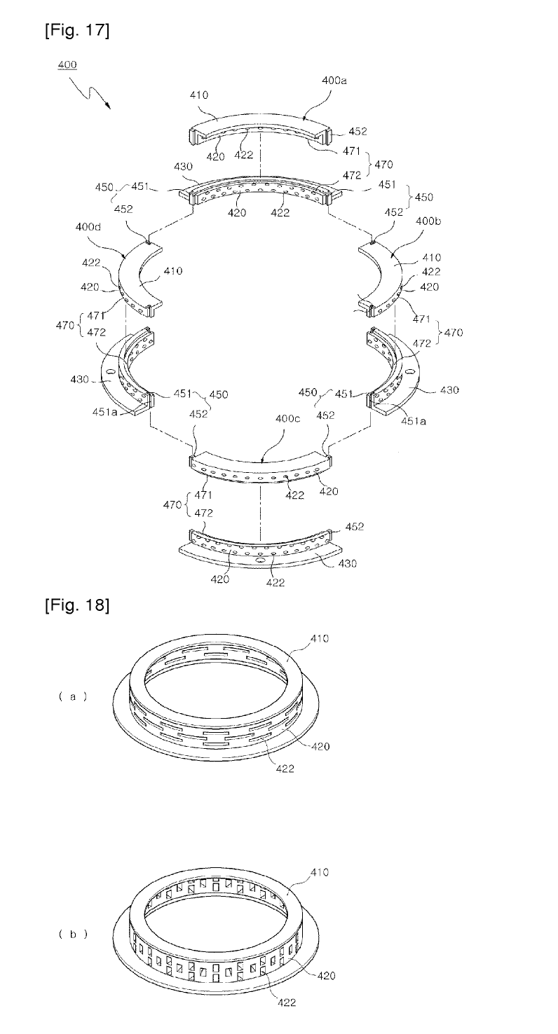

The vertical coupling structure 470 includes upper and lower jaws 471 and 472 formed at corresponding end portions of the sub parts 400e and 400f. When the sub parts 400e and 400f are engaged with each other, the upper jaw 471 may be laid on top of the lower jaw 472 and disposed inside the lower jaw 472, or the upper jaw 471 may be laid on top of the lower jaw 472 and disposed around the lower jaw 472. That is, the upper jaw 471 and the lower jaw 472 are coupled with each other as corresponding male-female joint parts. The vertically corresponding upper and lower jaws 471 and 472 of the sub parts 400e and 400f may have other shapes as well as that shown in the current embodiment. As shown in FIG. 17, the vertically divided substrate holder 400 of FIG. 15 can be re-divided in a circumferential direction.

By dividing the substrate holder 400 as explained above, when the substrate holder 400 is broken, only a broken part of the substrate holder 400 can be re-machined or replaced without having to re-machine or replace the substrate holder 400 wholly. Therefore, maintenance machining can be easily and rapidly performed, and maintenance costs can be reduced.

As shown in FIG. 18, the exhaust holes 422 formed in the substrate holder 400 of the above-described embodiments may have a slit-shape. The slit-shaped exhaust holes 422 may be arranged along the circumference of the sidewalls 420 at regular intervals as shown in FIG. 18(a), or the slit-shaped exhaust holes 422 may be arranged at regular intervals in a direction perpendicular to the circumferential direction of the sidewalls 420 as shown in FIG. 18(b). However, the shape and arrangement of the exhaust holes 422 formed in the sidewalls 420 can be different from those explained above. By varying the shape of the exhaust holes 422 as described above according to, for example, process conditions, reaction gas (plasma) injected toward the back surface of a substrate (S) can be exhausted more smoothly, and thus the back surface (particularly, the back surface edge portion) of the substrate (S) can be uniformly etched.

In the substrate processing apparatus of FIG. 2, the buffer member 600 is provided between the electrode 310 and the insulating plate 314 so as to connect the substrate holder 400 to a side of the electrode 310. The buffer member 600 includes a body 610, an elastic member 620 disposed inside the body 610, and a holder support 630 disposed at an upper portion of the elastic member 620.

The body 610 has a cylindrical or polyhedral shape with an opened top side, and a predetermined space is formed inside the body 610. The elastic member 620 is disposed in the predetermined space of the body 610 and is fixed to the inner bottom side of the body 610. The elastic member 620 may be a member such as a spring. The holder support 630 is disposed at the upper portion of the elastic member 620. The holder support 630 is partially inserted in the body 610 and protruded upward from the body 610. The outer surface of the body 610 of the buffer member 600 is coupled to the outer surface of the insulating plate 314, and an upper portion of the holder support 630 is coupled to a lower portion of the substrate holder 400. The buffer member 600 may be provided in plurality and spaced apart from the outer surface of the electrode 310. In this case, the buffer members 600 may be coupled to the insulating plate 314 along the circumference of the insulating plate 314.

If the electrode 310 and the substrate holder 400 are lifted until the substrate (S) supported on the top surface of the substrate holder 400 is spaced a predetermined distance from the shield member 200, the hard stoppers 210 formed on the bottom surface of the shield member 200 are engaged with the recesses 412 formed at the top surface of the substrate holder 400 so that the predetermined distance between the substrate (S) supported on the top surface of the substrate holder 400 and the shield member 200 can be stably maintained (in the case where the recesses 412 are not formed, the predetermined distance is stably maintained in a state where the bottom surfaces of the hard stoppers 210 make contact with the top surface of the substrate holder 400).

Next, if the electrode 310 is further lifted to adjust a plasma gap between the shield member 200 and the electrode 310, the elastic member 620 disposed inside the body 610 of the buffer member 600 is compressed. That is, only the electrode 310 is lifted in a state where the substrate holder 400 is fixed. Here, when the electrode 310 is lifted, the insulating plate 314 coupled to the bottom side of the electrode 310 is also lifted.

The elevating member 320 is connected to the bottom side of the insulating plate 314 supporting the electrode 310 to lift both the electrode 310 and the substrate holder 400. A driving unit (not shown) such as a motor may be connected to the elevating member 320 for providing a driving force to the elevating member 320.

In the related art, a portion of a ring-shaped stage of a substrate holder is opened so as to prevent collision or interference between the stage and a robot arm when a substrate is carried into a chamber and placed on the stage by the robot arm. Therefore, the entire edge portion of the back surface of the substrate is not supported on the stage. In this case, reaction gas injected toward the back surface of the substrate may leak through the opened portion of the stage, and plasma generated at the back surface of the substrate may also leak through the opened portion of the stage, or plasma discharge may be separated. Thus, if the back surface of the substrate is treated in this state, the etch uniformity decreases as it goes to the edge portion of the back surface of the substrate due to the unstable plasma at the back surface of the substrate.

However, according to the exemplary embodiments, a substrate carried into the chamber is first placed on the lift pins, and the stage of the substrate holder is constructed to have a ring shape forming a continuous closed curve. Therefore, almost the entire edge portion of the back surface of the substrate can be brought into contact with the top surface of the stage so as to prevent leakage of reaction gas injected toward the back surface of the substrate. Furthermore, according to the exemplary embodiments, the substrate holder includes a sidewall and penetration holes formed through the sidewall, so that reaction gas injected toward the back surface of a substrate can be uniformly distributed for generating plasma uniformly. Therefore, owning to the uniform plasma at the back surface of the substrate, the back surface of the substrate can be uniformly etched.

The substrate supporting apparatus 1000 may be constructed as follows.

Referring to FIG. 19, according to an exemplary embodiment, the substrate supporting apparatus 1000 includes an electrode unit 390 constituted by an electrode 310 and an insulating plate 314, a substrate holder 400 disposed at an upper side of the electrode unit 390, a buffer member 600 disposed between the electrode unit 390 and the substrate holder 400 to connect the electrode unit 390 and the substrate holder 400, and an elevating member 320 connected to the bottom side of the electrode unit 390 for simultaneously moving the electrode unit 390 and the substrate holder 400. The same description already given on the substrate holder 400 in the previous embodiment will be omitted.

The electrode unit 390 includes the electrode 310 and the insulating plate 314 coupled to the bottom surface of the electrode 310, and the substrate holder 400 is provided above the electrode unit 390 for supporting almost the entire edge portion of a substrate (S). The buffer member 600 is disposed between the electrode unit 390 and the substrate holder 400 for connecting the electrode unit 390 and the substrate holder 400.

A predetermined space is formed inside a body 610 of the buffer member 600, and the top side of the predetermined space is opened. In the predetermined space, an elastic member 620 is disposed, and a holder support 630 is disposed at an upper portion of the elastic member 620. The holder support 630 is coupled to a supporting part 430 of the substrate holder 400. The body 610 of the buffer member 600 is spaced apart from the outer surface of the electrode 310 and is connected to the outer surface of the electrode 310 through a connection part. The buffer member 600 may be provided in plurality and arranged along the outer circumference of the electrode 310 at predetermined intervals. The plurality of buffer members 600 may be coupled to the outer circumference of the electrode 310 individually or wholly. The elevating member 320 is connected to the bottom side of the electrode unit 390 for simultaneously moving the electrode unit 390 and the substrate holder 400. The insulating plate 314 provided at the bottom side of the electrode 310 may be omitted.

In the substrate processing apparatus of FIG. 1, the substrate holder 400 and the electrode 310 are moved by the driving unit 500 and the elevating member 320 that are individually controlled. However, in the substrate processing apparatus of FIG. 2, the buffer member 600 is provided to connect the substrate holder 400 to a side of the electrode unit 390 for simultaneously moving the electrode unit 390 and the substrate holder 400, so that the substrate processing apparatus can have a simple structure, and a sufficient space can be formed in the chamber 100. Furthermore, since the electrode unit 390 and the substrate holder 400 are simultaneously moved, a substrate (S) can be spaced apart from the electrode unit 390 uniformly, constantly, and horizontally. In addition, owing to the buffer member 600 disposed between the electrode unit 390 and the substrate holder 400, the electrode unit 390 can be lifted in a state where the substrate holder 400 is fixed, so as to adjust the plasma gap between the electrode unit 390 and the shield member 200 more precisely and easily.

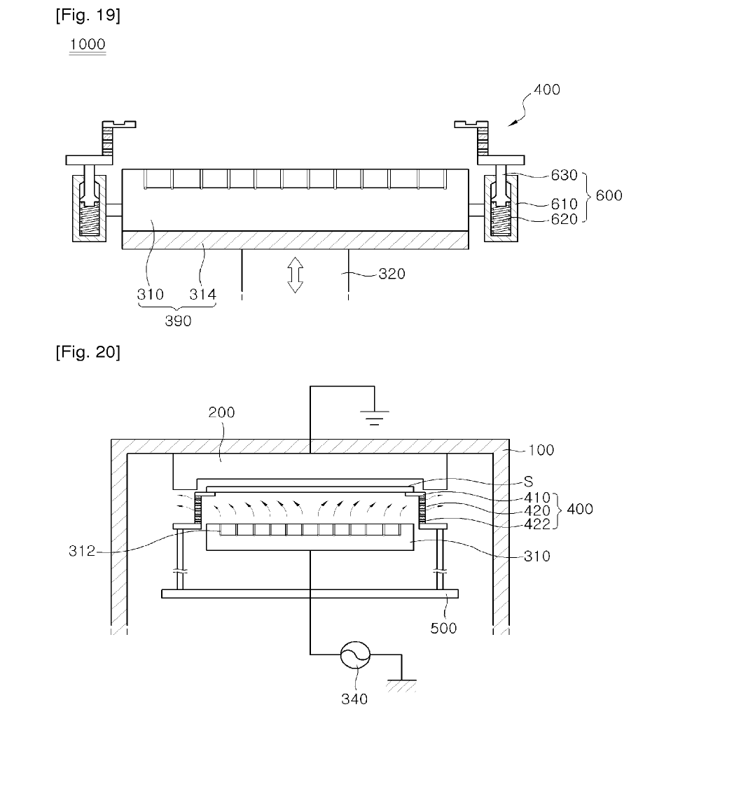

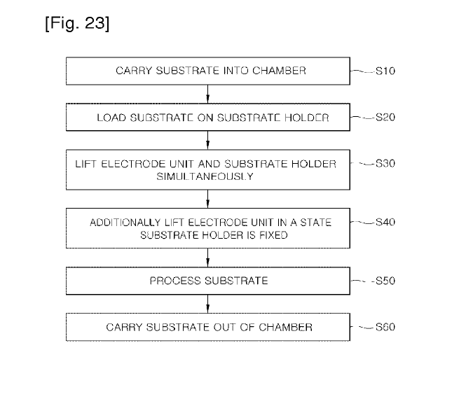

Hereinafter, with reference to FIGS. 20 through 23, explanations will be given on a substrate processing method using the substrate processing apparatus of FIG. 1 and a substrate processing method using the substrate processing apparatus of FIG. 2.

First, an explanation will now be given on a substrate processing method using the substrate processing apparatus of FIG. 1 with reference to FIG. 20.

If a substrate (S) is carried into the chamber 100 and placed on the top surfaces of the lift pins 350 by an external robot arm (not shown), the substrate holder 400 placed below the top surfaces of the lift pins 350 is lifted toward the shield member 200. At this time, as the substrate holder 400 is lifted, the edge portion of the substrate (S) placed on the lift pins 350 is entirely placed on the substrate holder 400 (specifically, on the top surface of the stage 410 of the substrate holder 400) that forms a closed curve having a predetermined width, and after the substrate (S) is placed on the substrate holder 400, the substrate holder 400 is further lifted until the substrate (S) is spaced a predetermined distance from the shield member 200. The predetermined distance between the substrate (S) and the shield member 200 may be about 0.5 mm or smaller to prevent generation of plasma at the front surface of the substrate (S).

After the substrate holder 400 is lifted until the substrate (S) is spaced apart from the shield member 200 by the predetermined distance, the electrode 310 is lifted by the elevating member 320 connected to the electrode 310 until the electrode 310 is spaced apart from the shield member 200 by a predetermined gap suitable for generating high-density plasma.

Next, reaction gas is injected from the gas supply unit 330 connected to the electrode 310 toward the back surface of the substrate (S) through the injection holes 312 formed through the electrode 310, and the injected reaction gas is uniformly distributed across the back surface of the substrate (S). That is, the sidewall 420 of the substrate holder 400 confines the reaction gas injected toward the back surface of the substrate (S) within the back surface of the substrate (S) so as to prevent escaping of the reaction gas from the center portion of the back surface of the substrate (S), and the exhaust holes 422 formed through the sidewall 420 are used to uniformly discharge the reaction gas in all directions for uniformly distributing the reaction gas staying at the back surface of the substrate (S).

Next, power is applied to the electrode 310 from the high-frequency power supply 340 connected to the electrode 310 so as to generate plasma uniformly between the electrode 310 and the shield member 200, that is, to generate plasma uniformly at the back surface of the substrate (S). At this time, the plasma stays at the space between the substrate (S) supported on the substrate holder 400 and the sidewall 420 of the substrate holder 400, and thus leakage of the plasma can be prevented and the plasma can be uniformly distributed across the entire back surface of the substrate (S). Since the plasma stays uniformly across the center and edge portions of the back surface of the substrate (S), etch uniformity at the back surface of the substrate (S) can be improved. The back surface of the substrate (S) is etched by the uniform plasma generated as described above. Owing to the uniform plasma (high-density plasma) generated at the back surface of the substrate (S), foreign substances such as thin layers and particles can be effectively removed from the back surface of the substrate (S), and the etch uniformity across the back surface of the substrate (S) can be improved.

Next, an explanation will now be given on a substrate processing method using the substrate processing apparatus of FIG. 2.

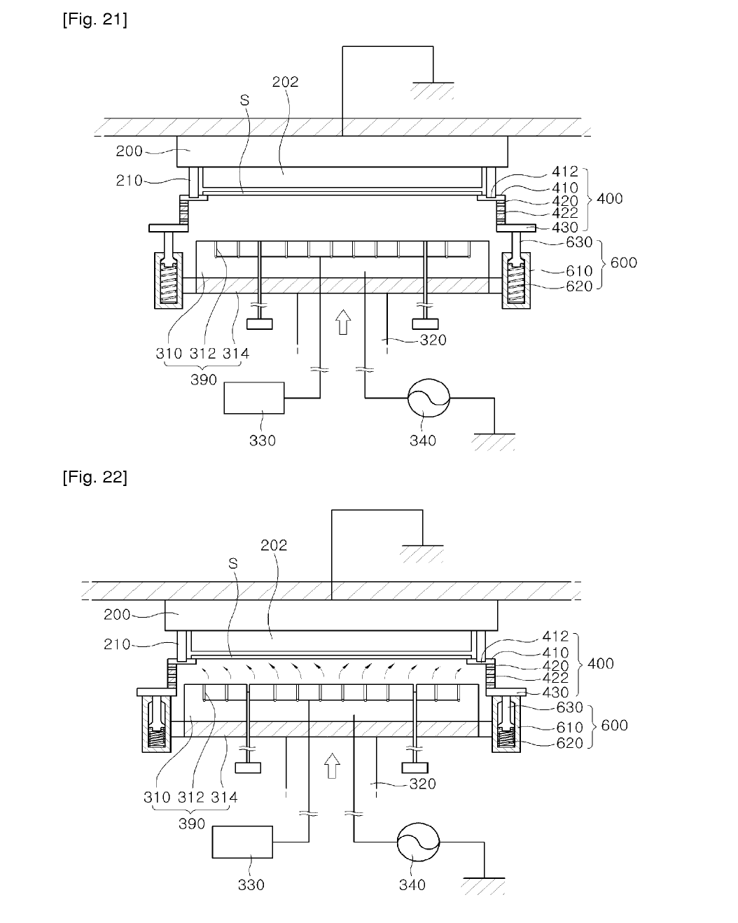

Referring to FIGS. 21 through 23, according to an exemplary embodiment, the substrate processing method includes: carrying a substrate into a chamber (operation S10), loading the substrate on a substrate holder (operation S20); simultaneously lifting the substrate holder and an electrode unit disposed under the substrate holder (operation S30); lifting the electrode unit furthermore in a state where the substrate holder is fixed (operation S40); processing the substrate (operation S50); and carrying the substrate outward (operation S60).

In detail, a pre-processed substrate (S) is horizontally carried into the chamber 100 by an external robot arm (not shown) disposed outside the chamber 100. The substrate (S) carried into the chamber 100 is moved above the top surfaces of the lift pins 350 disposed at lower positions inside the chamber 100 and is lowered to place the substrate (S) on the top surfaces of the lift pins 350 by the robot arm. In this way, the substrate (S) is carried into the chamber 100 in operation S10. At this time, the substrate holder 400 is placed at a wait position where the top surface of the substrate holder 400 is lower than the top surfaces of the lift pins 350.

Next, the electrode unit 390 and the substrate holder 400 connected to the electrode unit 390 are lifted toward the shield member 200 by the elevating member 320 connected to the electrode unit 390, and while the electrode unit 390 and the substrate holder 400 are lifted, the substrate (S) placed on the top surfaces of the lift pins 350 is placed on the top surface of the substrate holder 400. In this way, the substrate (S) is loaded on the substrate holder 400 in operation S20.

Next, the substrate holder 400 on which almost the entire edge portion of the substrate (S) is placed is further lifted, and as shown in FIG. 21, the hard stoppers 210 formed on the bottom surface of the shield member 200 are engaged with the recesses 412 formed in the top surface of the stage 410 of the substrate holder 400, and the electrode unit 390 and the substrate holder 400 are stopped. In this way, the electrode unit 390 and the substrate holder 400 are simultaneously lifted in operation S30. Then, the front surface of the substrate (S) placed on the top side of the substrate holder 400 is spaced apart from the bottom surface of the protrusion 202 formed on the bottom surface of the shield member 200 by approximately 0.5 mm or less.

Next, as shown in FIG. 22, the electrode unit 390 is further lifted by the elevating member 320 connected to the bottom side of the electrode unit 390 so as to adjust the (plasma) gap between the electrode unit 390 and the shield member 200. At this time, the elastic member 620 disposed inside the body 610 of the buffer member 600 connected between the electrode unit 390 and the substrate holder 400 is compressed, and thus only the electrode unit 390 is lifted in a state where the substrate holder 400 connected to the electrode unit 390 is stopped by the hard stoppers 210 formed on the bottom side of the shield member 200. In this way, in operation S40, the electrode unit 390 is further lifted in a state where the substrate holder is fixed.

Next, reaction gas is injected from the gas supply unit 330 connected to the electrode 310 toward the back surface of the substrate (S) through the injection holes 312 formed through the electrode 310, and the injected reaction gas is uniformly distributed across the back surface of the substrate (S). At this time, while the reaction gas is injected toward the back surface of the substrate (S) through the electrode 310, the exhaust holes 422 formed through the sidewall 420 of the substrate holder 400 are used to exhaust the injected reaction gas uniformly in almost all directions, so that the reaction gas injected toward the back surface of the substrate (S) can be uniformly distributed. Next, power is applied to the electrode 310 from the high-frequency power supply 340 connected to the electrode 310 so as to generate plasma uniformly between the electrode 310 and the shield member 200, specifically, at a space under the substrate (S). Then, foreign substances such as thin layers and particles are removed from the back surface of the substrate (S) by the plasma uniformly generated at the space under the substrate (S). In this way, the substrate (S) is processed in operation S50.

Next, as the elevating member 320 connected to the bottom side of the electrode unit 390 is moved downward, the compressed elastic member 620 returns to its original shape, and the electrode unit 390 and the substrate holder 400 are simultaneously moved downward. Next, as the substrate holder 400 is moved downward, the substrate (S) placed on the top surface of the substrate holder 400 is placed on the top surfaces of the lift pins 350, and then the electrode unit 390 and the substrate holder 400 are further lowered to their original positions where the top surface of the substrate holder 400 is lower than the top surfaces of the lift pins 350. Next, the substrate (S) placed on the top surfaces of the lift pins 350 is carried to the outside of the chamber 100 by the external robot arm. In the way, the substrate (S) is carried to the outside of the chamber 100 in operation S60.

Although the organic light emitting device has been described with reference to the specific embodiments, it is not limited thereto. Therefore, it will be readily understood by those skilled in the art that various modifications and changes can be made thereto without departing from the spirit and scope of the present invention defined by the appended claims.

1. A substrate supporting apparatus comprising:
an electrode unit;
a buffer member disposed at an outer circumference of the electrode unit;
a substrate holder disposed on the buffer member for spacing a substrate apart from the electrode unit by supporting an edge portion of the substrate; and
an elevating member configured to move the electrode unit and the substrate holder upward and downward.

2. The substrate supporting apparatus of claim 1, wherein the buffer member comprises:
a body in which a predetermined space is defined and having an opened top side;
an elastic member disposed in the predetermined space; and
a holder support disposed at an upper portion of the elastic member and extending upward from the opened top side of the body.

3. The substrate supporting apparatus of claim 2, wherein a lower surface of the substrate holder is supported on an upper surface of the holder support.

4. The substrate supporting apparatus of claim 1, wherein the electrode unit comprises:
an electrode; and
an insulating plate coupled to a lower surface of the electrode,
wherein the buffer member is coupled to an outer circumference of the electrode or the insulating plate.

5. A substrate processing apparatus comprising:
a chamber;
a shield member disposed in the chamber;
an electrode facing the shield member; and
a substrate holder disposed between the shield member and the electrode,
wherein the substrate holder comprises:
a ring-shaped stage configured to receive an edge portion of a substrate thereon;
a sidewall connected to a lower surface of the stage for supporting the lower surface of the stage; and
an exhaust hole formed in the sidewall.

6. The substrate processing apparatus of claim 5, further comprising a lift pin disposed in the chamber and inserted through the electrode.

7. The substrate processing apparatus of claim 5, wherein the electrode comprises an injection hole configured to inject gas therethrough.

8. The substrate processing apparatus of claim 5, further comprising a hard stopper protruding downwardly from a lower portion of the shield member.

9. The substrate processing apparatus of claim 8, further comprising a recess corresponding to the hard stopper and formed in an upper portion of the stage.

10. A substrate processing apparatus comprising:
a chamber;
a shield member disposed in the chamber;
an electrode unit facing the shield member;
a substrate holder disposed between the shield member and the electrode for supporting an edge portion of a substrate;
a buffer member connecting the electrode unit and the substrate holder; and
an elevating member connected to a lower portion of the electrode unit,
wherein the substrate holder comprises:
a ring-shaped stage configured to receive the edge portion of the substrate thereon;
a sidewall connected to a lower surface of the stage for supporting the lower surface of the stage; and
an exhaust hole formed in the sidewall.

11. The substrate processing apparatus of claim 10, further comprising a lift pin disposed in the chamber and inserted through the electrode unit.

12. The substrate processing apparatus of claim 10, wherein the electrode unit comprises an injection hole configured to inject gas therethrough.

13. The substrate processing apparatus of claim 10, further comprising a hard stopper protruding downwardly from a lower portion of the shield member.

14. The substrate processing apparatus of claim 10, wherein the buffer member comprises:
a body in which a predetermined space is defined and having an opened top side;
an elastic member disposed in the predetermined space; and
a holder support disposed at an upper portion of the elastic member and extending upward from the opened top side of the body.

15. The substrate processing apparatus of claim 13, further comprising a recess corresponding to the hard stopper and formed in an upper portion of the stage.

16. A substrate processing apparatus comprising:
a gas distribution plate configured to uniformly distribute reaction gas supplied from an outer source;
a hard stopper protruding downward from a lower edge portion of the gas distribution plate;
a lower electrode configured to interact with an upper electrode to form an electric field for exciting reaction gas supplied through the gas distribution plate into a plasma state; and
a side baffle vertically protruding from an edge portion of the lower electrode for uniformly exhausting plasma reaction gas therethrough in a lateral direction and making contact with the hard stopper when the lower electrode is lifted to limit the lifting of the lower electrode.

17. The substrate processing apparatus of claim 16, further comprising:
a lift pin driving unit configured to lift and lower a lift pin inserted through the lower electrode; and
a driving unit coupled to a shaft connected to a lower portion of the lower electrode for lifting and lowering the lower electrode.

18. The substrate processing apparatus of claim 17, further comprising:
an optical sensor configured to detect a gap between the gas distribution plate and a substrate by emitting laser beams through a plurality of penetration holes formed through the gas distribution plate; and
a control unit configured to receive a gap-sensing signal from the optical sensor and calculate the gap between the gas distribution plate and the substrate,
wherein when the calculated gap is greater than a predetermined gap value, the control unit determines that there is an error and generates an interlock signal.

19. The substrate processing apparatus of claim 17, wherein the number of the plurality of penetration holes formed through the gas distribution plate is three, and the plurality of penetration holes are disposed to be spaced apart from each other by the same distance on a circular arc.

20. The substrate processing apparatus of claim 17, wherein the hard stopper comprises a contact switch configured to be turned on when the hard stopper makes contact with the side baffle.

21. The substrate processing apparatus of claim 20, wherein when the contact switch is turned on, the control unit controls the driving unit to stop the lower electrode.

22. The substrate processing apparatus of claim 16, wherein non-reaction gas is discharged through a center portion of the gas distribution plate, and reaction gas is discharged toward an edge portion of the substrate through an edge portion of the gas distribution plate.

23. A substrate processing method comprising:
carrying a substrate into a chamber;
loading the substrate onto a substrate holder;
simultaneously lifting the substrate holder and an electrode unit disposed under the substrate holder;
processing the substrate; and
carrying the substrate out of the chamber.

24. The substrate processing method of claim 23, wherein after the simultaneous lifting of the substrate holder and the electrode unit, the substrate processing method further comprises additionally lifting the electrode unit while the substrate holder is stopped.

25. The substrate processing method of claim 24, wherein while the substrate holder is stopped, a buffer member connected between the substrate holder and the electrode unit is compressed to additionally lift the electrode unit.
